(19) United States
(12) Patent Application Publication
(10) Pub. No.: US 2004/0207065 A1
(43) Pub. Date: Oct. 21, 2004

(54) [STACK-TYPE MULTI-CHIP PACKAGE AND METHOD OF FABRICATING BUMPS ON THE BACKSIDE OF A CHIP]

(76) Inventors: Chih-Huang Chang, Tainan Hsien (TW); Shau-Chuo Wen, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,179

(22) Filed: Apr. 19, 2004

(30) Foreign Application Priority Data
Apr. 18, 2003 (TW) 92109018

(51) Int. Cl. H01L 23/02

(52) U.S. Cl. 257/686

(57) ABSTRACT

A stack-type multi-chip package at least comprising a substrate, a first chip, a second chip, a plurality of bump pads, a plurality of bumps, a plurality of first conductive wires, a plurality of second conductive wires and some packaging material. The backside of the first chip is attached to the substrate. The second chip is assembled to the active surface of the first chip. The bump pads are positioned on the backside of the second chip. The bumps are sandwiched between the first chip and the second chip such that the bumps are bonded to the first chip and the bump pads. The first chip and the second chip are electrically connected to the substrate through the first conductive wires and the second conductive wires. The packaging material encapsulates the first chip, the second chip, the bumps, the first conductive wires and the second conductive wires.

### CROSS REFERENCE TO RELATED APPLICATIONS

This application claims the priority benefit of Taiwan application serial no. 92109018, filed Apr. 18, 2003.

### BACKGROUND OF INVENTION

1. Field of Invention

The present invention relates to a stack-type multi-chip package and a method of fabricating bumps on the backside of a chip. More particularly, the present invention relates to a package comprising a multiple of chips stacked via bumps separating the chips and a corresponding method of fabricating the bumps on the backside of the chips.

2. Description of Related Art

The fabrication of integrated circuits (IC) in the semiconductor industry can be roughly divided into two major stages: an integrated circuit (IC) fabrication stage and an IC packaging stage. In general, a chip is an end product of a series of operations on a wafer including ion doping, circuit laying, dielectric-layer depositing and wafer dicing. After the production of a chip, a packaging operation is performed such that the chip is electrically connected to a substrate through conductive wires or bumps, for example. By packaging the chip, the chip as well as the electrical connection between the chip and the substrate is protected.

As electronic technologies continue to advance, more multi-functional and personalized electronic products are generated. To meet aesthetic or functional demands of most users, most electronic products are designed to be as light and compact as possible. Hence, many types of high-density semiconductor packages have been developed. Multi-chip package module is one of the high-density semiconductor packages currently in great demand. One type of multi-chip module has a plurality of chips stacked over each other and enclosed by molding compound. Because a multi-chip package module normally has short transmission paths, its electrical performance will improve significantly.

FIG. 1 is a schematic cross-sectional view of a conventional stack-type multi-chip package module. The stack-type multi-chip package module 100 in FIG. 1 comprises a pair of chips 110, 120, a substrate 130, a plurality of conductive wires 140, 150, some packaging material 160 and a plurality of solder balls 170. The chips 110, 120 are sequentially stacked on an upper surface 132 of the substrate 130. Through an adhesive material 180, the chips 110 and 120 are bonded together but isolated from each other by a padding layer. The adhesive material 180 is an epoxy resin, for example. Through the conductive wires 140 and 150, both the lower chip 110 and the upper chip 120 are electrically connected to the substrate 130. The packaging material 160 encapsulates the chips 110, 120 and the conductive wires 140, 150. The solder balls 170 are attached to the underside 134 of the substrate 130.

In the aforementioned stack-type multi-chip package module 100, the adhesive material 180 forms a padding that separates the two chip 110, 120 so that the conductive wires 140 is able to bond with bonding pads on the active surface 112 of the chip 110. However, using the adhesive material to form a padding layer that controls the distance of separation between the chips 110 and 120 has some problems. Because the adhesive material 180 is sticky and soft, stacking the chip 120 perfectly flat relative to the underlying chip 110 through the layer of adhesive material 180 is difficult. If there is some slant in the upper chip 120, the chip 120 may touch some of the conductive wires 140 below and lead to possible short circuit between the conductive wires 140. Ultimately, performance of the multi-chip package module 100 will be seriously affected.

To resolve this issue, an alternative stack-type multi-chip package module is shown in FIG. 2. FIG. 2 is a schematic cross-sectional view of another conventional stack-type multi-chip package module. In FIG. 2, an additional dummy die 280 is sandwiched between a lower chip 210 and an upper chip 220 so that the lower chip 210 and the upper chip 220 are separated from each other similar to the insertion of a padding layer. The dummy die 280 is bonded to the lower chip 210 and the upper chip 220 through adhesive material layers 282 and 284 respectively. Since it is possible to fabricate the dummy die 280 to whatever thickness one demands, distance of separation between the surface of the upper chip 210 and the lower chip 220 can be precisely adjusted. Nevertheless, using the dummy die 280 to set the distance between the chips 210 and 220 demands a multiple of additional steps. Prior to bonding the dummy die 280 to the chips 210 and 220, a piece of wafer has to be meticulously polished to a precise thickness and then the polished wafer has to be cut up into a dummy dies of the right size. In other words, the fabrication of the stack-type multi-chip modules 200 is more costly and time-consuming to fabricate.

### SUMMARY OF INVENTION

Accordingly, one object of the present invention is to provide a stack-type multi-chip package and a method of fabricating bumps on the backside of a chip. The package utilizes bumps to serve as padding for distancing neighboring chips so that the conductive wires bonded to a lower chip are prevented from contacting the lower surface of an upper chip.

A second object of this invention is to provide a stack-type multi-chip package and a method of fabricating bumps on the backside of a chip. The package has bump pads formed on the backside of an upper chip such that bumps can be firmly attached to the various bump pads on the backside of the upper chip.

To achieve these and other advantages and in accordance with the purpose of the invention, as embodied and broadly described herein, the invention provides a stack-type multi-chip package. The stack-type multi-chip package at least comprises a substrate, a first chip, a second chip, a plurality of second bump pads, a plurality of bumps, a plurality of first conductive wires, a plurality of second conductive wires and some packaging material. The first chip has a first active surface and a first back-side. The first chip has a plurality of first bonding pads and a plurality of first bump pads. The first bonding pads are set up in the peripheral region on the first active surface and the first bump pads are positioned on the first active surface. The first chip is attached to the upper surface of the substrate through the first backside. One end of each conductive wire is electrically connected to the first bonding pad and the other end of the first conductive wire is electrically connected to the substrate. The second chip has a second active surface and a second backside. The second chip has a plurality of second bonding pads. The second bonding pads are positioned in the peripheral region on the second active surface. The second chip is assembled to the first active surface of the first chip with the second backside facing the first chip. The second bump pads are located on the second backside of the second chip. The bumps are positioned between the first chip and the second chip such that one end of each bump bonds with one of the first bump pads while the other end of each bump bonds with one of the second bump pads. One end of the second conductive wire is electrically connected to one of the second bonding pads while the other end of the second conductive wire is electrically connected to the substrate. The packaging material encapsulates the first chip, the second chip, the bumps, the first conductive wires and the second conductive wires.

This invention also provides a method of fabricating bumps on the backside of a chip. The method includes the following steps. First, a chip with an active surface having a plurality of bonding pads thereon and a backside is provided. Thereafter, a metallic layer is formed on the backside of the chip. The metallic layer is patterned to form at least a bump pad. Finally, a bump is attached to the bump pad.

This invention also provides an alternative method of fabricating bumps on the backside of a chip. The method includes the following steps. First, a chip with an active surface having a plurality of bonding pads thereon and a backside is provided. Thereafter, a mask having at least an opening is placed on the backside of the chip so that the backside of the chip is exposed. A metallic layer is formed over the mask and the exposed backside of the chip. Afterwards, the mask is removed. The remaining metallic layer on the backside of the chip becomes a bump pad. Finally, a bump is attached to the bump pad.

In brief, the stack-type multi-chip package structure according to this invention utilizes the bumps to serve as padding separating the first chip from the second chip, wherein not only the first chip is the same size as the second chip or the second chip is larger than the first chip in size, so that the first conductive wires are prevented from contacting the backside of the second chip.

In addition, this invention also provides a method of fabricating bumps on the backside of the second chip. To assemble the first chip and the second chip together, one end of each bump is bonded to the first bump pad on the first chip while the other end of the bump is bonded to the second bump pad on the second chip. Hence, the first chip and the second chip are firmly joined together via the bumps.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional stack-type multi-chip package module.

FIG. 2 is a schematic cross-sectional view of another conventional stack-type multi-chip package module.

FIG. 3 is a schematic cross-sectional view of a stack-type multi-chip package module according to one preferred embodiment of this invention.

FIGS. 4A to 4F are schematic cross-sectional views showing the progression of steps for fabricating second bump pads on the backside of a second chip according to a first preferred embodiment of this invention.

FIGS. 5A and 5B are schematic cross-sectional views showing the steps for attaching a bump to the second bump pad according to the first preferred embodiment of this invention.

FIGS. 6A through 6C are schematic cross-sectional views showing the progression of steps for fabricating second bump pads on the backside of a second chip according to a second preferred embodiment of this invention.

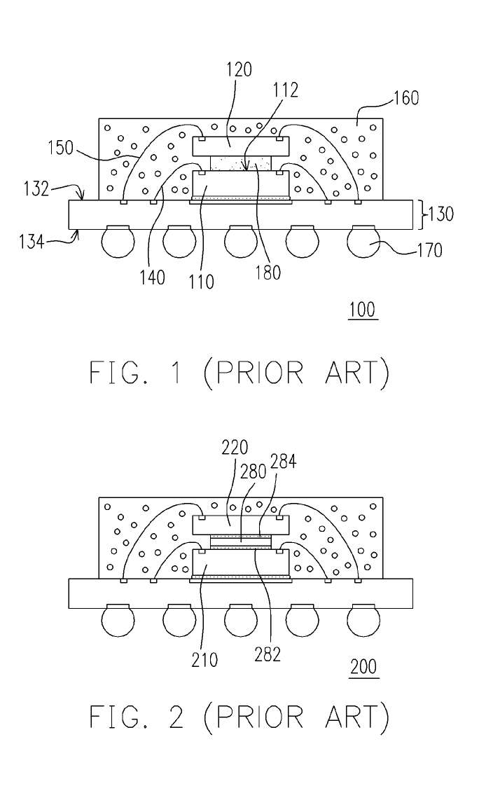

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

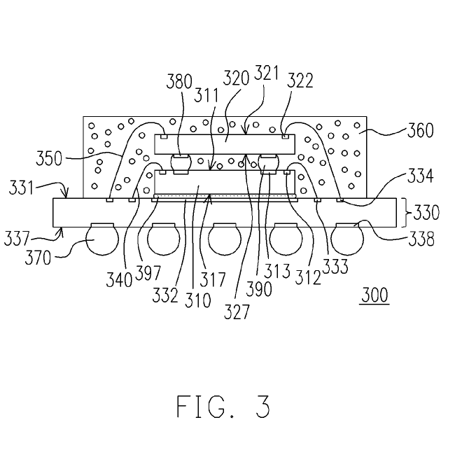

FIG. 3 is a schematic cross-sectional view of a stack-type multi-chip package module according to one preferred embodiment of this invention. The stack-type multi-chip package 300 in FIG. 3 comprises a substrate 330, a first chip 310, a second chip 320, a plurality of first conductive wires 340, a plurality of second conductive wires 350, a plurality of second bump pads 380, a plurality of bumps 390, some packaging material 360 and a plurality of solder balls 370.

The substrate 330 has an upper surface 331 and a lower surface 337. The substrate 330 also has a die pad 332, a plurality of first contacts 333, a plurality of second contacts 334 and a plurality of third contacts 338. The die pad 332, the first contacts 333 and the second contacts 334 are set up on the upper surface 331 of the substrate 330. The first contacts 333 are disposed on the peripheral region around the die pad 332. The second contacts 334 are disposed on the peripheral region around the first contacts 333. The third contacts 338 are organized into an area array on the lower surface 337 of the substrate 330.

The first chip 310 has a first active surface 311 and a first backside 317. The first chip 310 also has a plurality of first bonding pads 312 and a plurality of first bump pads 313 in the peripheral region on the first active surface 311 of the chip 310. The first bump pads 313 are positioned close to the first bonding pads 312, for example. The first backside 317 of the chip 310 is attached to the die pad 332 on the substrate 330 through an adhesive material 397. One end of the first conductive wire 340 is electrically connected to one of the first bonding pads 312 on the chip 310 while the other end of the conductive wire 340 is electrically connected to one of the first contacts 333 on the substrate 330.

The second chip 320 has a second active surface 321 and a second backside 327. The second chip 320 also has a plurality of second bonding pads 322 in the peripheral region on the second active surface 321 of the chip 320. The second bump pads 380 are disposed on the second backside 327 of the chip 320. The second bump pads 380 are fabricated using gold, for example. Each bump 390 is bonded to one of the first bump pads 313 on the first chip 310 and one of the second bump pads 380 on the second backside 327 of the second chip 320. The bumps 380 are positioned in the peripheral region on the first active surface 311 of the first chip 310 close to the first bonding pads 312. Hence, the second chip 320 is firmly attached to the first chip 310 through the bumps 390 with the second backside 327 of the second chip 320 faces the first active surface 311 of the first chip 310. The bumps 390 can be fabricated from a material including lead-tin alloy, gold or a lead-free substance such as tin-silver-copper alloy, for example. Preferably, the bumps 390 have a height between 200 μm to 300 μm, for example.

One end of each second conductive wire 350 is electrically connected to one of the second bonding pads 322 on the second chip 320 while the other end of the second conductive wire 350 is electrically connected to one of the second contacts 334 on the substrate 330. The packaging material 360 encapsulates the first chip 310, the second chip 320, the bumps 390, the first conductive wires 340 and the second conductive wires 350. The solder balls 370 are attached to various third contacts 338 on the substrate 330.

The bumps 390 within the aforementioned stack-type multi-chip package module 300 effectively serves as a padding that separates the second chip 320 from the first chip 310, wherein not only the first chip 310 is the same size as the second chip 320 or the second chip 320 is larger than the first chip 310 in size, so that the first conductive wires 340 are prevented from contacting the second backside 327 of the second chip 320.

In the following, a method of joining the first chip 310 and the second chip 320 is described. There are two principle methods of joining the first chip 310 and the second chip 320 together. In the first method, bumps 390 are attached to the second bump pads 380 on the second chip 320 through patterned electroplating, printing, bump attaching using a wire-bonding machine or solder ball implanting. Thereafter, the second chip 320 is placed over the first chip 310 with the bumps 390 aligned with various first bump pads 313 on the first chip 310. A reflow process is performed so that the bumps 390 and the first bump pads 313 are bonded together. In this way, the first chip 310 and the second chip 320 are firmly joined together.

In a second method, bumps 390 are attached to the first bump pads 313 on the first chip 310 through patterned electroplating, printing, bump attaching using a wire-bonding machine or solder ball implanting. Thereafter, the second chip 320 is placed over the first chip 310 such that the second bump pads 380 align with various bumps 390. A reflow process is performed so that the bumps 390 and the second bump pads 380 are bonded together. In this way, the first chip 310 and the second chip 320 are firmly joined together.

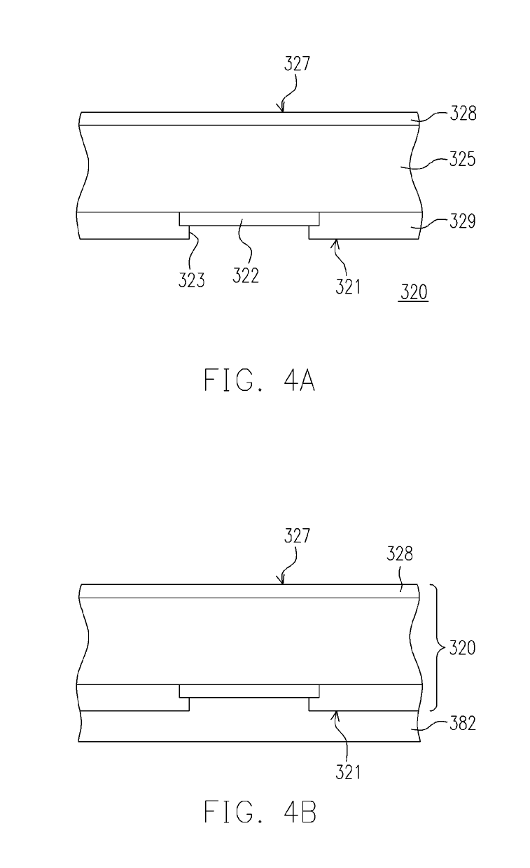

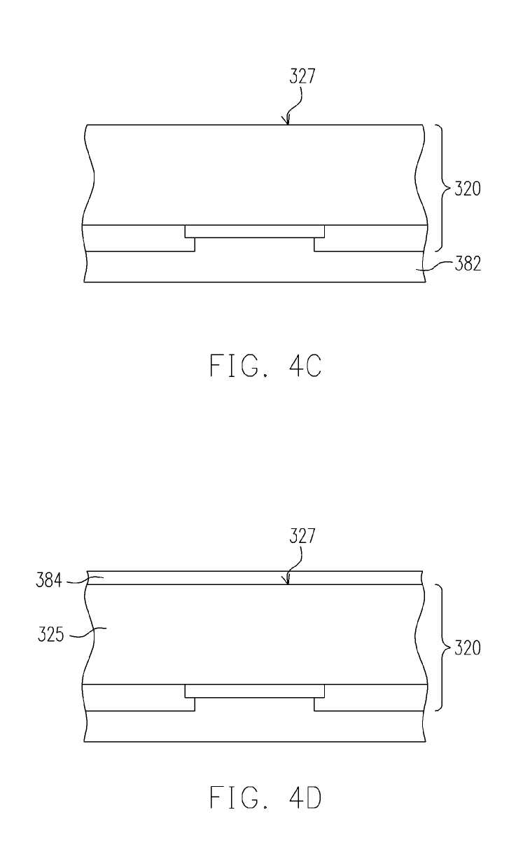

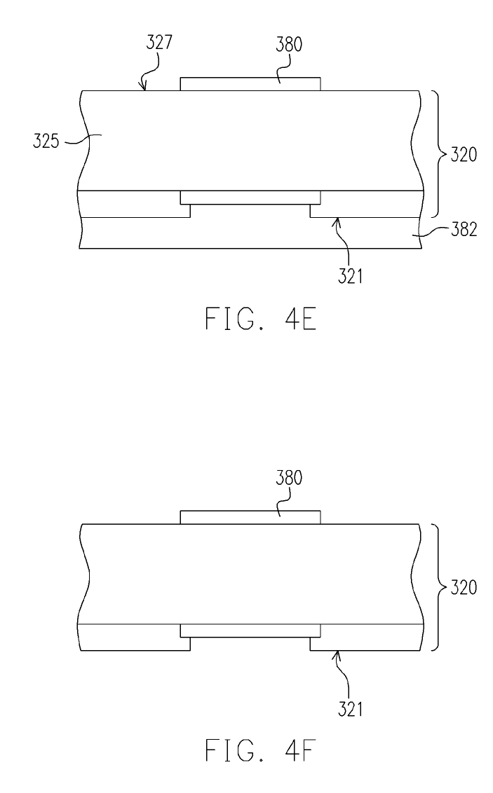

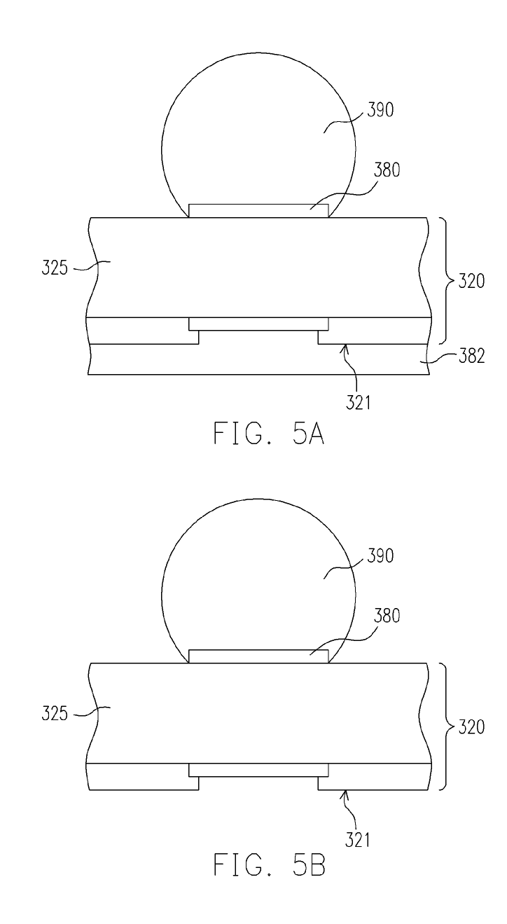

FIGS. 4A to 4F are schematic cross-sectional views showing the progression of steps for fabricating second bump pads on the backside of a second chip according to a first preferred embodiment of this invention. As shown in FIG. 4A, a second chip 320 comprising a substrate 325 and two passivation layers 328, 329 on the respective sides of the substrate 325 is provided. The passivation layer 328 is positioned over the second backside 327 of the chip 320 and the passivation layer 329 is positioned over the second active surface 321 of the second chip 320. The passivation layer 329 has a plurality of openings 323 (only one is shown) that expose the second bonding pads 322. The substrate 325 is fabricated using a material such as silicon and the passivation layers 328, 329 are fabricated using a material such as silicon oxide, silicon nitride or phosphosilicate glass.

As shown in FIG. 4B, a protective film 382 is formed over the second active surface 321 of the second chip 320 to protect electronic devices (not shown) at the second active surface 321. Thereafter, a polishing or etching operation is carried out to remove the passivation layer 328 on the substrate 325 so that the second backside 327 of the chip 320 is exposed as shown in FIG. 4C. Obviously, if the source wafer provided by a manufacturer has no passivation layer 328, the step for removing the passivation layer 328 can be skipped.

As shown in FIG. 4D, a metallic layer 382 is formed over the second backside 327 of the chip 320 through sputtering, electroplating or electroless plating. The metallic layer 384 is fabricated using gold, for example. Thereafter, photolithographic and etching processes are carried out in sequence to pattern the metallic layer 384 and form a second bump pad 380 on the backside 327 of the substrate 325 as shown in FIG. 4E. Finally, the protective film 382 on the second active surface 321 of the chip 320 is removed to form a structure as shown in FIG. 4F. If bumps 390 have already been attached to the first chip 310 as shown in FIG. 3, a thermal lamination or a reflow process can be performed to join the bumps 390 and the second bump pads 380 together. Thus, the first chip 310 and the second chip 320 are joined together but separate from each other by a gap through the bumps 390.

FIGS. 5A and 5B are schematic cross-sectional view showing the steps for attaching a bump to the second bump pad according to the first preferred embodiment of this invention. After forming the second bump pads 380 but before removing the protective film 382, using patterning and electroplating processes, a screen printing process, a bump-bonding process by a wire-bonding machine or a ball-implanting process, bumps 390 are attached on the second bump pads 380 as shown in FIG. 5A. Thereafter, the protective film 382 on the second active surface 321 of the second chip 320 is removed to form a structure as shown in FIG. 5B. Finally, as shown in FIG. 3, a reflow process can be performed to join the bumps 390 and the first bump pads 313 of the first chip 310 together. Thus, the first chip 310 and the second chip 320 are joined together.

Through forming second bump pads 380 on the second backside 327 of the second chip 320 and using the bumps 390 to join up various first bond pads 313 with corresponding second bump pads 380, the first chip 310 and the second chip 320 are firmly attached to each other.

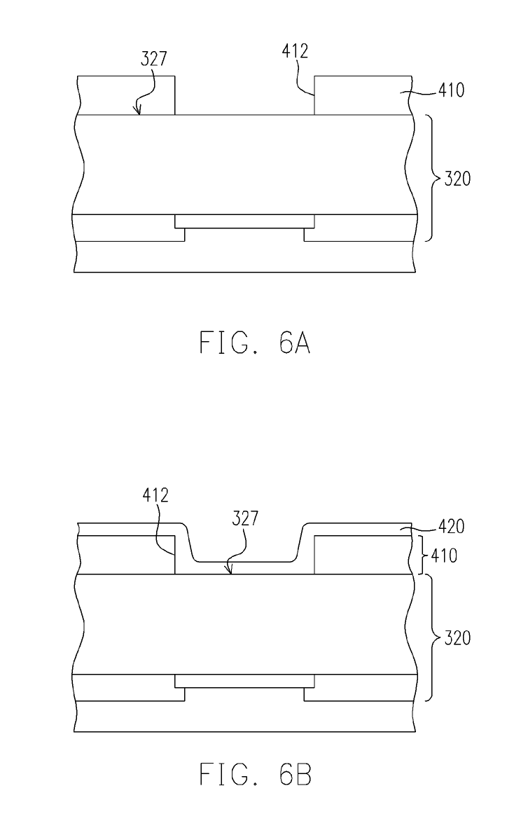

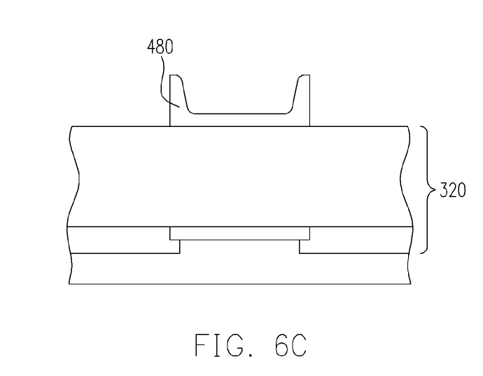

However, the aforementioned method of forming the second bump pads are not the only one. Other methods are also possible. FIGS. 6A through 6C are schematic cross-sectional views showing the progression of steps for fabricating second bump pads on the backside of a second chip according to a second preferred embodiment of this invention. As shown in FIG. 6A, after removing the passivation layer 328 (as shown in FIG. 4B), a mask 410 is placed on the second backside 327 of the second chip 320. The mask 410 has a plurality of openings 412 (only one is shown) that exposes the second backside 327 of the chip 320. As shown in FIG. 6B, a sputtering, an electroplating or an electroless plating process is carried out to form a metallic layer 420 over the mask 410 and exposed backside 327 of the chip 320. The mask 410 is removed to retain a remaining metallic layer 420 on the second backside 327 of the chip 320 and serve as a second bump pad 480.

In the aforementioned embodiments, the stack-type chip package contains only two chips. In practice, the invention permits the stacking of more than two chips over each other.

In summary, major advantages of the stack-type multi-chip package module and the method of fabricating bumps on the backside of a chip according to this invention include: 1. Using the bumps as a bonding and a padding structure, the second chip is firmly attached to the first chip without a direct contact so that conductive wires bonded to the first chip is prevented from touching the backside of the second chip. 2. Through the process of forming a second bump pad on the backside of the second chip and using bumps to join up the first bump pads on the first chip with the second bump pads on the second chip, the first chip and the second chip are solidly attached.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A stack-type multi-chip package structure, comprising:
a substrate;
a first chip with a first active surface having a plurality of first bonding pads and a plurality of first bump pads thereon and a first backside, wherein the first bonding pads are positioned in the peripheral region on the first active surface and the first bump pads are positioned on the first active surface, and the backside of the first chip is attached to the substrate;
a plurality of first conductive wires, wherein one end of each first conductive wire is electrically connected to one of the first bonding pads and the other end of the first conductive wire is electrically connected to the substrate;
a second chip with a second active surface having a plurality of second bonding pads thereon and a second backside, wherein the second bonding pads are positioned in the peripheral region on the second active surface, and the second chip assembles with the first active surface of the first chip such that the second backside faces the first chip;
a plurality of second bump pads set up on the second backside of the second chip, wherein the second bump pads are fabricated using a metallic material;
a plurality of bumps positioned between the first chip and the second chip such that one end of the bumps are bonded to the first bump pads and the other end of the bumps are bonded to the second bump pads;
a plurality of second conductive wires, wherein one end of the second conductive wire is electrically connected to one of the second bonding pads and the other end of the second conductive wire is electrically connected to the substrate; and
a packaging material encapsulating the first chip, the second chip, the bumps, the first conductive wires and the second conductive wires.

2. The package structure of claim 1, wherein material constituting the second bump pads comprises gold.

3. The package structure of claim 1, wherein material constituting the bumps comprises gold.

4. The package structure of claim 1, wherein material constituting the bumps comprises lead-tin alloy.

5. The package structure of claim 1, wherein material constituting the bumps comprises lead-free alloy.

6. The package structure of claim 5, wherein material constituting the bumps comprises tin-silver-copper alloy.

7. The package structure of claim 1, wherein the bumps are positioned in the peripheral region of the first active surface close to the first bonding pads.

8. The package structure of claim 1, wherein the second chip is larger than the first chip in size.

9. A chip structure having bumps thereon, comprising:
a chip with an active surface having a plurality of bonding pads thereon and a backside;
at least a bump pad set up on the backside of the chip, wherein the bump pad is fabricated using a metallic material; and
at least a bump attached to the bump pad.

10. The chip structure of claim 9, wherein material constituting the bump comprises lead-tin alloy.

11. The chip structure of claim 9, wherein material constituting the bump comprises lead-free alloy.

12. The chip structure of claim 11, wherein material constituting the bump comprises tin-silver-copper alloy.

13. The chip structure of claim 9, wherein material constituting the bump pad comprises gold.

14. The chip structure of claim 9, wherein material constituting the bump comprises gold.

15. A method of fabricating bumps on the backside of a chip, comprising the steps of:
providing a chip with an active surface having a plurality of bonding pads thereon and a backside;
forming at least a bump pad on the backside of the chip; and
attaching a bump to the bump pad.

16. The method of claim 15, wherein the step of forming the bump pad on the backside of the chip further comprises:
forming a metallic layer on the backside of the chip; and
patterning the metallic layer to form the bump pad.

17. The method of claim 15, wherein the step of forming the bump pad on the backside of the chip further comprises:
putting a mask on the backside of the chip, wherein the mask has at least an opening so that the backside of the chip is exposed;
forming a metallic layer over the mask and the exposed backside of the chip; and
removing the mask so that the remaining metallic layer on the backside of the chip becomes the bump pad.

18. The method of claim 15, wherein before forming the bump pad on the backside of the chip, the method further comprises forming a protective film on the active surface of the chip.

19. The method of claim 15, wherein the chip further comprises a passivation layer coated on the backside of the chip so that the passivation layer is removed before forming the bump pad on the backside of the chip.

20. The method of claim 15, wherein during the step of attaching bumps to the bump pads, patterning and electroplating process, a printing process, a bump-bonding process by a wire-bonding machine or a ball-implanting process are performed.
